(19) United States
(12) Patent Application Publication
(10) Pub. No.: US 2004/0145057 A1
(43) Pub. Date: Jul. 29, 2004

(54) Capacitor and method for fabricating the same

(76) Inventor: Hyung-Bok Choi, Ichon-shi (KR)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/664,779

(22) Filed: Sep. 16, 2003

(30) Foreign Application Priority Data
Dec. 30, 2002 (KR) 2002-86395
Dec. 30, 2002 (KR) 2002-86400

(51) Int. Cl. H01L 23/48

(52) U.S. Cl. 257/758

(57) ABSTRACT

A method for fabricating a capacitor of a semiconductor device which includes the steps of: forming an inter-layer insulating layer on a substrate; forming a contact hole exposing a partial portion of the substrate by etching the inter-layer insulating layer; a storage node contact buried into the contact hole such that the surface of the storage node contact is at the same plane level as the surface of the inter-layer insulating layer; forming a storage node oxide layer on the inter-layer insulating layer; forming a storage node hole exposing the storage node contact by etching the storage node oxide layer; forming a supporting hole hollowed in downward direction by recessing or removing partially an upper portion of the exposed storage node contact; and forming a storage node having a cylinder structure and being electrically connected to the storage node contact.

### FIELD OF THE INVENTION

The present invention relates to a semiconductor device; and, more particularly, to a capacitor and a method for fabricating the same.

### Description of Related Arts

It is a recent trend in a semiconductor device that an area for a capacitor has been reduced as levels of integration, minimization and high-speed have been highly increased. Even though the semiconductor device is highly integrated and minimized, it is essential to secure a capacitance of the capacitor for driving the semiconductor device.

As for securing the capacitance of the capacitor, there have been suggested various storage node structures such as a cylinder type, a stack type and a concave type so as to maximize efficient surface areas of the storage node within a limited area.

Also, the height of the storage node is increased to secure the capacitance of the capacitor.

FIGS. 1A to 1C are cross-sectional views showing a metal insulator silicon (MIS) capacitor fabricated by a conventional method.

Referring to FIG. 1A, an inter-layer insulating layer 12 is formed on a substrate 11. Then, the inter-layer insulating layer 12 is etched to form storage node contact holes exposing partial portions of the substrate 11. At this time, each storage node contact hole typically exposes a source/drain region of a transistor, a doped silicon layer, an epitaxially grown silicon layer and so on.

Next, a polysilicon layer is deposited on the inter-layer insulating layer 12 until filling the storage node contact holes. A recess etch-back process takes place until a surface of the inter-layer insulating layer 12 is exposed and planarized thereafter. As a result, polysilicon plugs 13 buried into the storage node contact holes are formed. At this time, each polysilicon plug 13 is a storage node contact (SNC).

Continuous to the polysilicon plug 13 formation, a nitride layer 14, which is an etch barrier layer, and a storage node oxide layer 15, which determines the height of the storage node are sequentially deposited.

Then, a storage node mask is formed on the storage node oxide layer 15. The storage node oxide layer 15 and the nitride layer 14 are consecutively etched with use of the storage node mask as an etch mask so as to form a storage node hole 16 in which a storage node is formed. Herein, the storage node hole 16 has a concave pattern. Since the storage node oxide layer 15 is thicker, the storage node hole 16 has an inclined lateral wall after the storage node oxide layer 15 is etched. As a result, the width of its bottom portion is narrower than that of its upper portion.

Referring to FIG. 1B, a chemical vapor deposition (CVD) technique is used to deposit a doped silicon layer on the storage node oxide layer 15 including the storage node hole 16. An oxide layer or a photosensitive film is formed on the doped silicon layer until filling the storage node hole 16.

Next, the doped silicon layer formed on portions except for the storage node hole 16 is removed through the use of an etch-back process or a chemical mechanical polishing (CMP) process. As a result of this removal, a storage node 17 having a cylinder structure is formed and the oxide layer and the photosensitive film are removed thereafter. Herein, the storage node 17 is constructed with the doped silicon layer and is also referred to as a lower electrode.

With reference to FIG. 1C, the storage node oxide layer 15 is removed by using a wet type dip-out process. At this time, the nitride layer 14 supports the storage node 17.

Although not illustrated in the drawings, a dielectric layer and a plate node, which is also called an upper electrode, are formed on the storage node 17 exposed after the removal of the storage node oxide layer 15, whereby a metal insulator silicon (MIS) capacitor is completed.

However, after the removal of the storage node oxide layer 15 with use of wet dip-out process, a bridge is formed between the storage nodes 17 or the storage node 17 may be pulled-out.

Particularly, the bridge formation between the storage nodes 17 and the pulling-out of the storage node 17 are caused by a shortage in a critical dimension of the bottom portion of the storage node 17; a decrease in structural strength of the storage node 17 caused by the above shortage; and a decreased quality of an opening due to a bad etching locally occurring during the etching process applied to the storage node oxide layer 15.

To improve the structural strength of the storage node, it is suggested to use storage node oxide layers having different values of wet etch selectivity.

FIGS. 2A to 2C are cross-sectional views showing a capacitor fabricated by a conventional method.

With reference to FIG. 2A, an inter-layer insulating layer 22 is formed on a substrate 21 in which a semiconductor circuit including a transistor and a bit line is formed. Then, the inter-layer insulating layer 22 is etched to form storage node contact holes, each exposing a partial portion of the substrate 21. At this time, the storage node contact hole exposes typically a source/drain region of the transistor, a doped silicon layer, an epitaxially grown silicon layer or the like.

Next, a titanium silicide layer 23 is formed on the substrate 21 exposed in the storage node contact hole. At this time, the titanium silicide layer 23 is formed by initially depositing a titanium layer and performing a thermal process thereafter. The non-reacted titanium layer is removed by a wet etching so that the titanium silicide layer 23 is formed solely within the storage node contact hole.

A conductive nitride is then deposited on the inter-layer insulating layer 22 until filling the storage node contact hole. A CMP process is subsequently performed for planarization and continued until exposing a surface of the inter-layer insulating layer 22. After the CMP process, a storage node contact plug 24 made of the conductive nitride and buried into the storage node contact hole is formed.

After forming the storage node contact plug 24, a storage node formation process proceeds.

A nitride layer 25 and a first and a second oxide layers 26A and 26B are sequentially deposited on the inter-layer insulating layer 22 including the storage node contact plug 24. Herein, the nitride layer 25 is an etch barrier layer and the first and the second storage node oxide layers 26A and 26B determine a height of the storage node 28. At this time, the first and the second storage node oxide layers 26A and 26B are double layers of the oxide layer having different values of wet etch selectivity. Especially, the first storage node oxide layer 26A has a higher wet etching selectivity value than that of the second storage node oxide layer 26B.

Next, a storage node mask is formed on the first and the second oxide layers 26A and 26B, and then a dry etching process is applied to the first and the second storage node oxide layers 26A and 26B by using the storage node mask as an etch mask so as to form each area for a storage node, e.g., each storage node hole 27.

The first and the second storage node oxide layers 26A and 26B are proceeded with a wet etching through a dip process using a wet chemical so that a width of the storage node hole 27 is widened. That is, in case the dip process is applied to the first and the second storage node oxide layers 26A and 26B having different values of wet etching selectivity, the first storage node oxide layer 26A is etched faster than the second storage node oxide layer 26B, and this different rate of the etching results in a bottom portion of the storage node hole 27 being wider than an upper portion of the storage node hole 27. Referring to FIG. 2B, a surface of the storage node contact plug 24 is exposed by etching the nitride layer 25, and then, a doped silicon layer is deposited on an entire surface including the storage node hole 27 through the use of a CVD technique. An oxide layer or a photosensitive film is formed on the doped silicon layer until filling the storage node hole 27.

Next, the doped silicon layer except for a portion formed on the storage node hole 27 is removed by employing an etch-back process or a CMP process so that the storage node 28 made of the doped silicon layer is formed. Herein, the storage node 28 is also called lower electrode and has a cylinder structure. After forming the storage node 28, the oxide layer or photosensitive film is removed.

Referring to FIG. 2C, the first and the second storage node oxide layers 26A and 26B are removed by employing a wet type dip-out process. At this time, the nitride layer 25 supports a bottom portion of the storage node 28.

Although it is not shown in the drawings, a dielectric layer and a plate node, which is called upper electrode, are sequentially formed on the storage node 28 exposed after the removal of the first and the second storage node oxide layers 26A and 26B, whereby a capacitor formation is completed.

According to the prior art, double oxide layers having different values of wet etching selectivity are used as the storage node oxide layers 26A and 26B determining a capacitance of the storage node in order to increase the capacitance of the capacitor.

However, since only the nitride layer 25 and the first storage node oxide layer 26A support the bottom portion of the storage node 28 in the above-preferred embodiment, there still occurs the bridge formation between the storage nodes and the pulling-out phenomenon after performing the wet type dip-out process to the storage node oxide layers 26A and 26B.

The bridge formation and the pulling-out phenomenon of the storage node 28 may further result in immediate occurrences of errors in a corresponding cell and a drastic decrease of wafer yields.

### SUMMARY OF THE INVENTION

It is, therefore, an object of the present invention to provide a capacitor capable of suppressing a bridge from being formed between storage nodes and the storage node from being pulled-out and a method for fabricating the same.

In accordance with an aspect of the present invention, there is provided a method for fabricating a capacitor of a semiconductor device, including the steps of: forming an inter-layer insulating layer on a substrate; forming a contact hole exposing a partial portion of the substrate by etching the inter-layer insulating layer; forming a storage node contact having the same plane level of a surface of the inter-layer insulating layer as being buried into the contact hole; forming a storage node oxide layer on the inter-layer insulating layer; forming a storage node hole exposing the storage node contact by etching the storage-node oxide layer; forming a supporting hole having a hollow form in a downward direction by recessing or removing partially an upper portion of the storage node contact exposed by the storage node hole; and forming a storage node having a cylinder structure and being electrically connected to the storage node contact wherein a bottom portion of the storage node is disposed in the support hole to thereby be supported by the supporting hole and the inter-layer insulation layer.

In accordance with another aspect of the present invention, there is also provided a method for fabricating a capacitor of a semiconductor device, including the steps of: forming an inter-layer insulating layer on a substrate; forming a contact hole exposing a partial portion of the substrate by etching the inter-layer insulating layer; forming a storage node contact having a plane level identical to a surface of the inter-layer insulating layer as being buried into the contact hole; forming a storage node oxide layer constructed with a double layer of an upper layer and a lower layer, wherein an etch selectivity ratio of the upper layer formed on the inter-layer insulating layer is higher than that of the lower layer; forming a storage node hole exposing the storage node contact by etching the storage node oxide layer; widening a width of the storage node hole and simultaneously forming an under-cut region at the lower layer of the storage node oxide layer; forming a supporting hole hollowed in a downward direction by recessing or removing a partial portion of an upper portion of the storage node contact exposed by the storage node hole with its width widened; and forming a storage node having a cylinder structure and being connected electrically to the storage node contact as a bottom region of the storage node within the storage node hole is supported by the supporting hole and the under-cut region.

In accordance with still another aspect of the present invention, there is also provided a capacitor of a semiconductor device, including: a substrate; an inter-layer insulating layer having a contact hole exposing a partial portion of the substrate and being formed on the substrate; a storage node contact providing a supporting hole at an upper region of the contact hole and filling a partial portion of the contact hole; and a storage node being connected to the storage node contact wherein a bottom portion of the storage node is inserted and secured into the supporting hole.

In accordance with still another aspect of the present invention, there is provided a method for fabricating a capacitor of a semiconductor device, including the steps of: forming an inter-layer insulating layer on a substrate; forming a storage node contact connected to the substrate by passing through the inter-layer insulating layer; forming a multi-layered insulation supporting element on the inter-layer insulating layer, the multi-layered insulation supporting element exposing the storage node contact and including at least one layer providing an under-cut region; and forming a cylindrical storage node electrically connected to the storage node contact as a bottom region of the storage node is inserted into the under-cut region of the multi-layered insulation supporting element.

In accordance with still further aspect of the present invention, there is provided a method for fabricating a capacitor of a semiconductor device, including the steps of: forming an inter-layer insulating layer on a substrate; forming a storage node contact connected to the substrate by passing through the inter-layer insulating layer; forming a storage node supporting layer on the inter-layer insulating layer in a manner that an insulation layer is inserted into a space between a first etch barrier layer and a second etch barrier layer; forming a storage node insulating layer on the storage node supporting layer; forming a storage node hole by etching the storage node insulating layer and the storage node supporting layer to make an etching process be stopped at the first etch barrier layer; removing selectively the storage node insulating layer and the storage node supporting layer to widen a width of the storage node hole and simultaneously form an under-cut region in between the second etch barrier layer and the first etch barrier layer; forming a cylindrical storage node connected to the storage node contact as a bottom region of the storage node formed in the storage node hole is inserted into the under-cut region; and removing selectively the storage node insulating layer.

### BRIEF DESCRIPTION OF THE DRAWING(S)

The above and other objects and features of the present invention will become apparent from the following description of the preferred embodiments given in conjunction with the accompanying drawings, in which:

FIGS. 1A to 1C are cross-sectional views showing a metal insulator silicon (MIS) capacitor fabricated by a conventional method;

FIGS. 2A to 2C are cross-sectional views showing a capacitor fabricated by the conventional method;

FIG. 3 is a cross-sectional view showing a capacitor structure in accordance with a first preferred embodiment of the present invention;

FIGS. 4A to 4F are cross-sectional views describing a method for fabricating the capacitor illustrated in FIG. 3;

FIG. 5 is a cross-sectional view showing a capacitor structure in accordance with a second preferred embodiment of the present invention;

FIGS. 6A to 6G are cross-sectional views explaining a method for fabricating the capacitor illustrated in FIG. 5;

FIG. 7 is a cross-sectional view showing a capacitor structure in accordance with a third preferred embodiment of the present invention;

FIGS. 8A to 8F are cross-sectional views demonstrating a method for fabricating the capacitor illustrated in FIG. 7;

FIG. 9 is a cross-sectional view showing a capacitor structure in accordance with a forth preferred embodiment of the present invention; and

FIGS. 10A to 10F are cross-sectional views describing a method for fabricating the capacitor illustrated in FIG. 9.

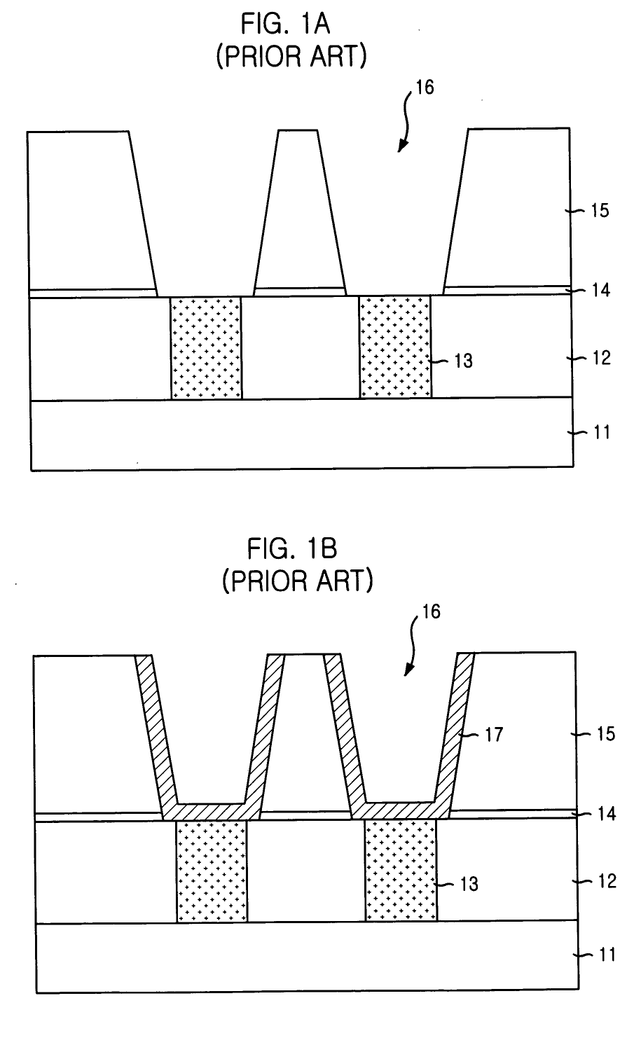

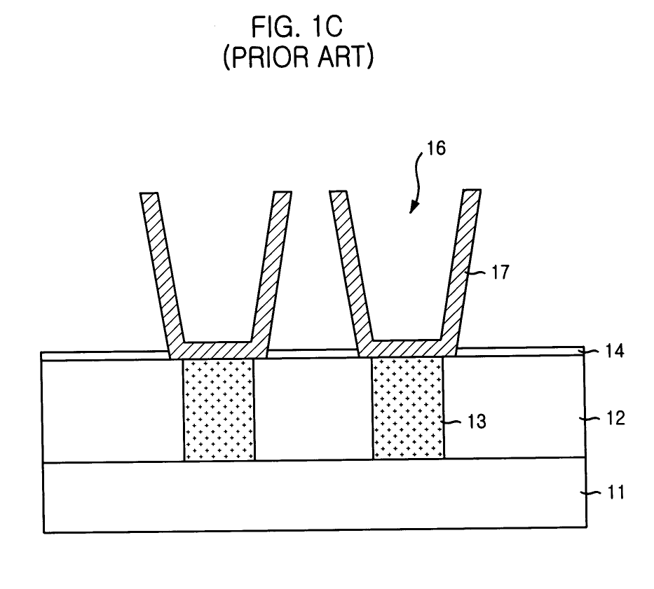

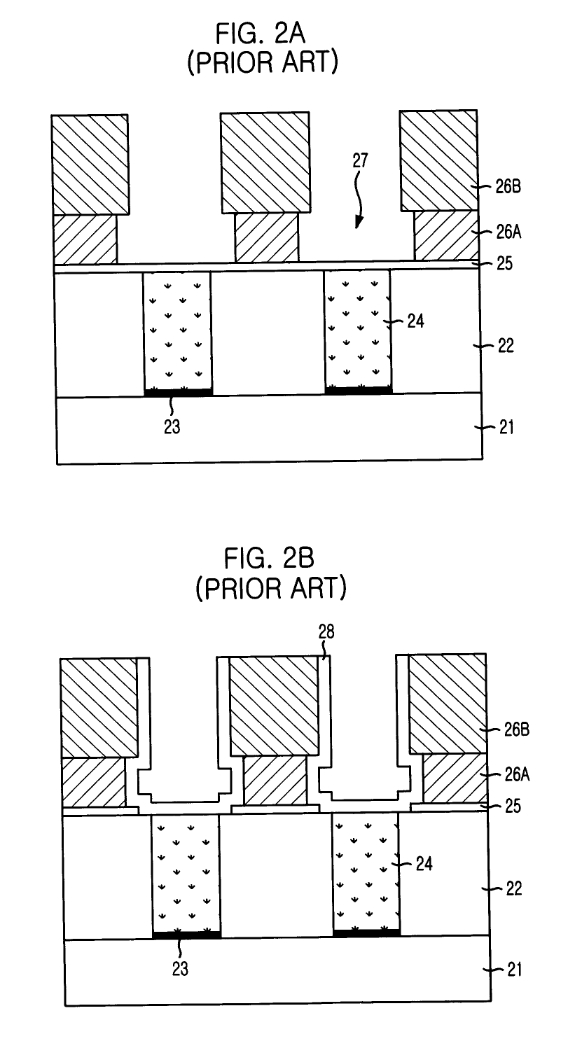

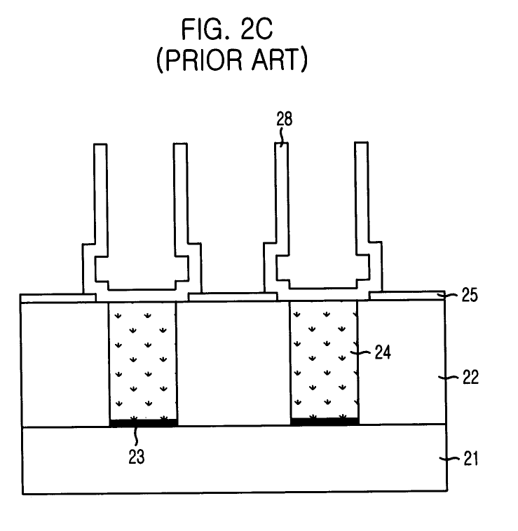

### DETAILED DESCRIPTION OF THE INVENTION

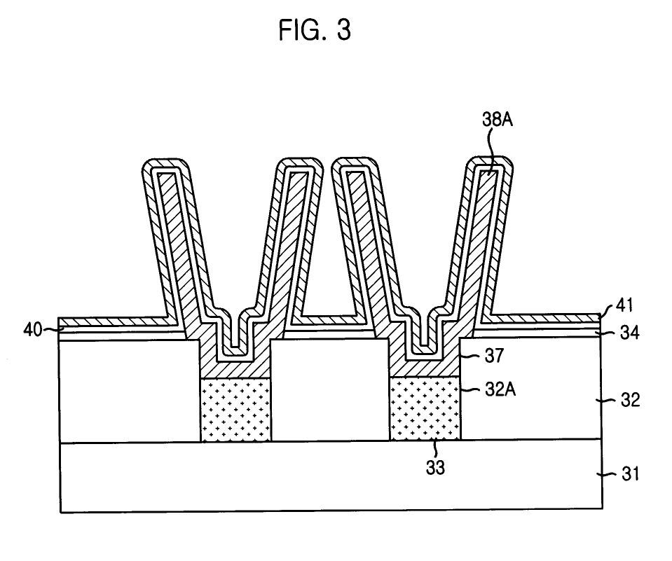

FIG. 3 is a cross-sectional view showing a capacitor structure in accordance with a first preferred embodiment of the present invention.

Referring to FIG. 3, the capacitor in accordance with the first preferred embodiment includes: a substrate 31 providing at least a transistor and a bit line; an inter-layer insulating layer 32 formed on the substrate 31; a polysilicon plug 33 filling a partial portion of a contact hole 32A that passes through the inter-layer insulating layer 32 and exposes a partial portion of the substrate 31; a supporting hole 37 forming the rest of the contact hole 32A; a storage node 38A of which bottom portion is filled into the supporting hole 37 and supported by a nitride layer 34 formed on the inter-layer insulating layer 32, the storage node 38A having a cylinder structure and being connected to the polysilicon plug 33; a dielectric layer 40 formed on the storage node 38A; and a plate node 41 stacked on the dielectric layer 40. It is noted that the bottom portion of the storage node 38A supported by the supporting hole 37 and the nitride layer 34 has a smaller critical dimension than its upper portion.

In such a capacitor illustrated in FIG. 3, it is possible to prevent a bridge formation between the storage nodes 38A and a pulling-out of the storage node 38A since the bottom portion of the storage node 38A is supported by being extended into the supporting hole 37 provided to an upper portion of the contact hole 32A occupying an upper portion of the polysilicon plug 33.

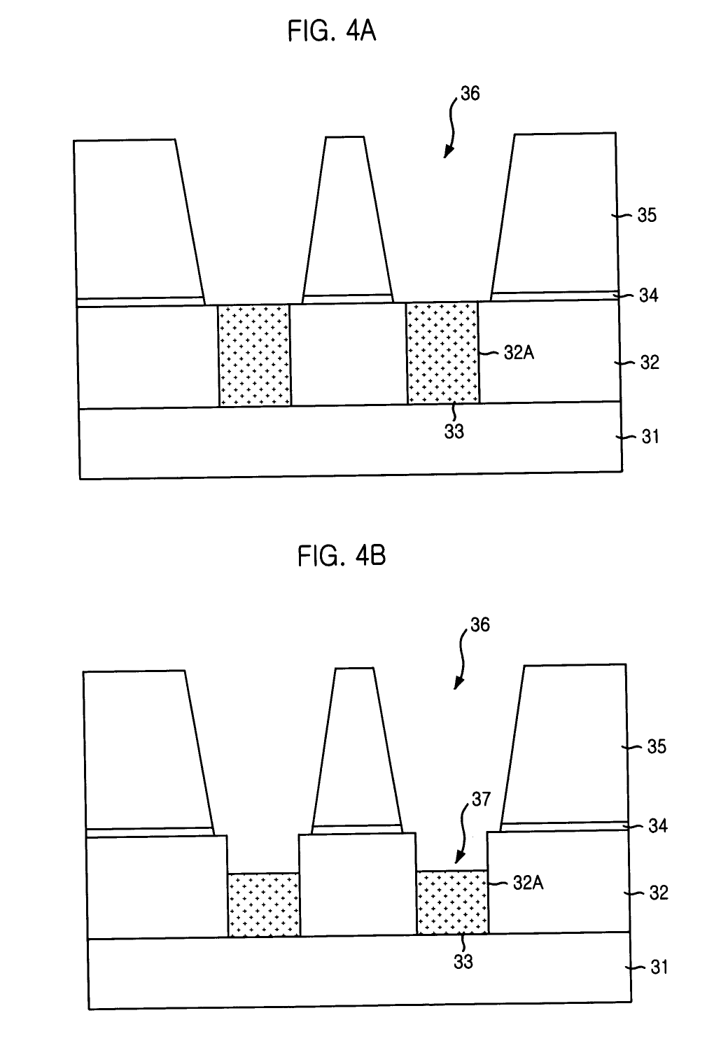

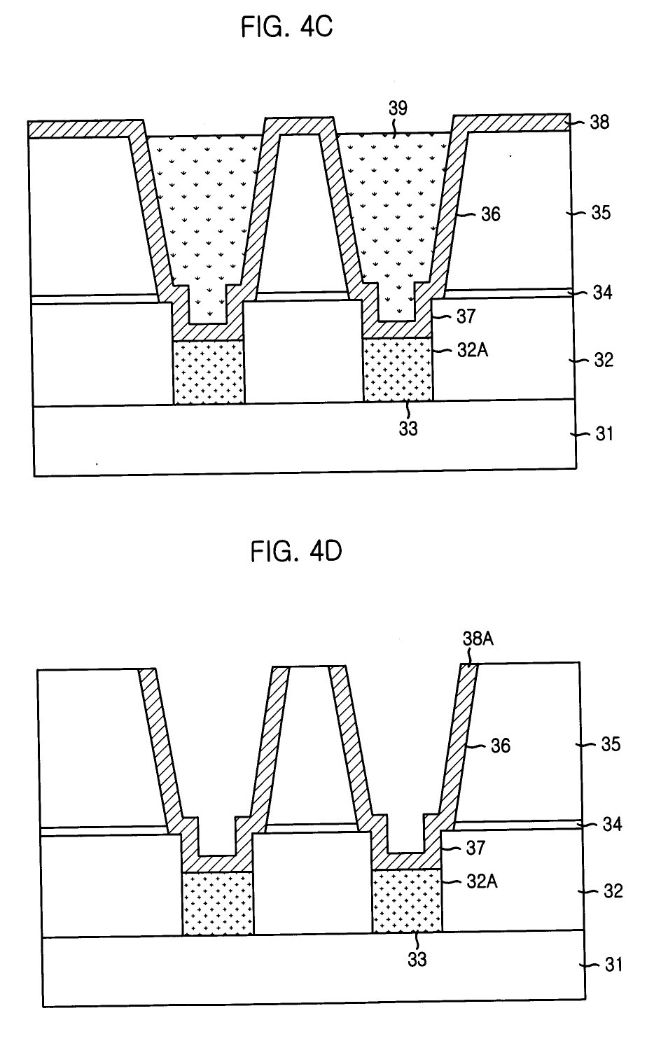

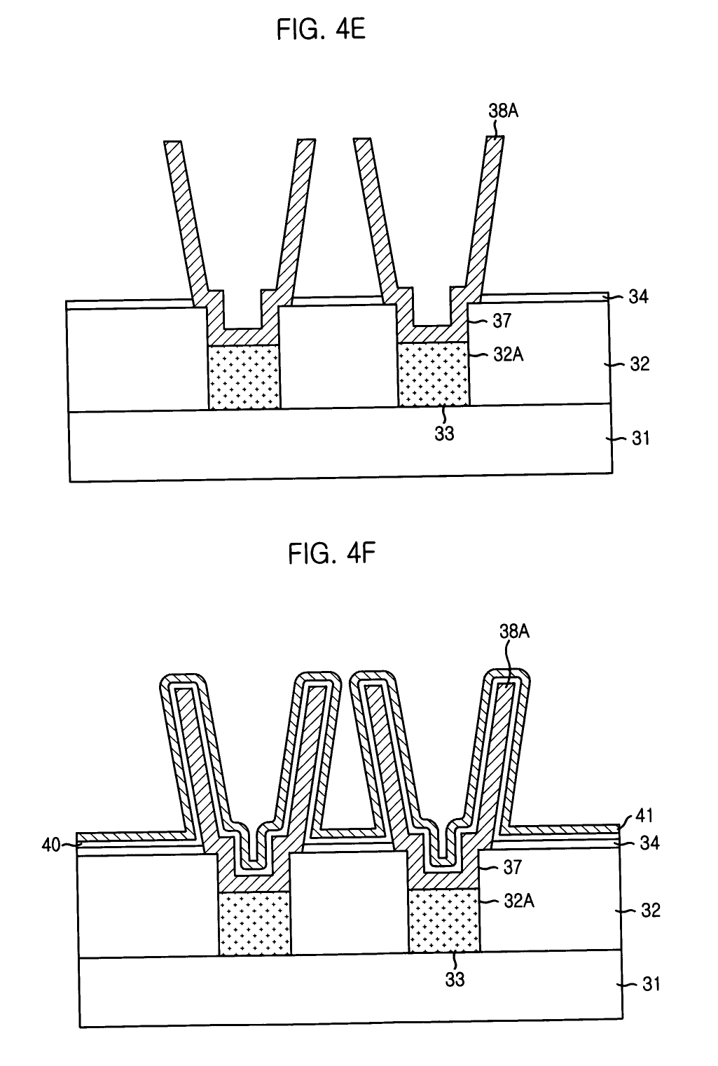

FIGS. 4A to 4F are cross-sectional views explaining a method for fabricating the capacitor illustrated in FIG. 3.

Referring to FIG. 4A, the inter-layer insulating layer 32 is formed on the substrate 31 providing a transistor and a bit line. Then, the inter-layer insulating layer 32 is etched to form contact holes 32A, each exposing a partial portion of the substrate 31. At this time, the contact hole 32A exposes typically a source/drain region of the transistor, a doped silicon layer, an epitaxially grown silicon layer or the like.

Next, a polysilicon layer is deposited on the inter-layer insulating layer 32 until filling the contact hole 32A, and a recess etch-back process or a chemical mechanical polishing (CMP) process is preformed for planarization and continued until exposing a surface of the inter-layer insulating layer 32. After the planarization of the polysilicon layer, the polysilicon plug 33 is buried into the contact hole 32A such that the surface of the polysilicon plug 33 is at the same plane level as that of the inter-layer insulating layer 32.

Subsequently, the nitride layer 34 and a storage node oxide layer 35 are sequentially formed on the inter-layer insulating layer 32 including the polysilicon plug 33. At this time, the total thickness of the nitride layer 34 and the storage node oxide layer 35 ranges from about 6000 Å to about 20000 Å. In particular, the thickness of the nitride layer 34 ranges from about 100 Å to about 2000 Å. Also, the storage node oxide layer 35 is a single oxide layer deposited through a chemical vapor deposition (CVD) technique. Also, the storage node oxide layer 35 uses any one selected from a group consisting of undoped silicate glass (USG), phospho silicate glass (PSG), boro phospho silicate glass (BPSG) and plasma enhanced tetra ethyl ortho silicate (PETEOS).

Then, a storage node mask is formed on the storage node oxide layer 35 and used as an etch mask to perform a dry etching process to the storage node oxide layer 35. The nitride layer 34 is consecutively proceeded with the dry etching process so as to form a storage node hole 36.

With reference to FIG. 4B, an upper portion of the polysilicon plug 33 exposed beneath a bottom of the storage node hole 36 is recessed again to form supporting holes 37. At this time, the supporting hole 37 is hollowed in with a predetermined distance from the bottom of the storage node hole 36. Meanwhile, a dry or wet etching process is used to recess the polysilicon plug 33.

As for the dry etching process for recessing the polysilicon plug 33, an etch selectivity ratio of the polysilicon layer with respect to the storage node oxide layer 35 is about 40 to 1, and a target thickness ranges from about 500 Å to about 5000 Å.

As for the wet etching process, a chemical solution of NH₄OH and H₂O mixed in a ratio of about 10:1 to about 1:500 or another chemical solution of HF and HNO₃ mixed in a ratio of about 20:1 to about 1:100 is used. Herein, the above ratio is the volume-based one. Also, the above recessing procedure using such mixing chemical solution takes place in a dipping bath whose temperature is maintained in a range from about 4° C. to about 100° C. for about 5 to 3600 seconds. A target etching thickness ranges from about 500 Å to about 5000 Å.

The supporting hole 37 formation can be also applied to a case that the storage node contact is not a polysilicon plug. That is, the supporting hole 37 can be formed by removing an upper portion of the storage node contact through the use of a dry etch selectivity value greater than a specifically set value and a chemical solution.

Referring to FIG. 4C, a doped silicon layer 38 is deposited on an entire surface including the supporting hole 37 by using a CVD technique. At this time, the doped silicon layer 38 is deposited to the bottom of the supporting hole 37. Also, it is possible to apply a double or stacked layer of a doped silicon layer and an undoped silicon layer in addition to the doped silicon layer 38.

Next, a photosensitive film, which is an etch-back barrier layer 39, is formed on the doped silicon layer 38 until filling the supporting hole 37 and the storage node hole 36. At this time, an oxide layer can be used as the etch-back barrier layer 39.

Then, a partial exposure and developing process is performed to make the etch-back barrier layer 39 remained only in the storage node hole 36.

With reference to FIG. 4D, the doped silicon layer 38 except for a portion formed in the storage node hole 36 proceeds with an etch-back process by using the remaining etch-back barrier layer 39 as an etch barrier so as to form the storage node 38A having a cylinder structure. The storage node 38A is also made of the doped polysilicon layer 38. Subsequent to the storage node 38A formation, the remaining etch-back barrier layer 39 is removed. The above-described process is called storage node isolation process.

The storage node 38A is formed through the above-described series of etch-back processes and has a structure wherein a bottom portion of the storage node 38A is inserted or filled into the supporting hole 37. Even though the storage node 38A is formed into the storage node hole 36 whose width becomes narrower going downward, the supporting hole 37 is precedently formed before forming the storage node 38A such that a bottom portion of the storage node 38A is inserted into the supporting hole 37. Therefore, the supporting hole 37 functions to reinforce the structural strength of the storage node 38A.

Meanwhile, the storage node isolation process can be proceeded by alternatively performing a CMP process to the doped silicon layer 38 until exposing a surface of the storage node oxide layer 35 after making the photosensitive film or the oxide layer remain only within the storage node hole 36.

Referring to FIG. 4E, the storage node oxide layer 35 is removed through a wet type dip-out process using a HF-based chemical solution. At this time, the wet type dip-out process is taking place in a dipping bath whose temperature is maintained in a range between about 4° C. to about 80° C. for about 10 to 3600 seconds. Since the nitride layer 34 acts as an etch barrier of the wet type dip-out process applied to the storage node oxide layer 35, it is possible to prevent losses of the inter-layer insulating layer 32.

It is also possible to prevent the storage node 38A from falling from its position due to the fact that the nitride layer 34 and the supporting hole 37 more firmly support the bottom portion of the storage node 38A having the cylinder structure.

As shown in FIG. 4F, the dielectric layer 40 and the plate node 41 are sequentially formed on the storage node 38A, whereby the MIS capacitor formation is completed. At this time, the dielectric layer 40 is deposited to a thickness ranging from about 50 Å to about 500 Å by using any one material selected from a group consisting of SiO₂, SiO₂/Si₃N₄, TaON, Ta₂O₅, TiO₂, Ta—Ti—O, Al₂O₃, HfO₂, HfO₂/Al₂O₃, SrTiO₃, (Ba, Sr)TiO₃ and (Pb, Sr)TiO₃. The plate node 41 is deposited by employing a sputtering technique, a CVD technique or an atomic layer deposition (ALD) technique and patterned thereafter. Particularly, the deposition thickness of the plate node 41 ranges from about 50 Å to about 500 Å by using TiN, Ru, Ir or Pt.

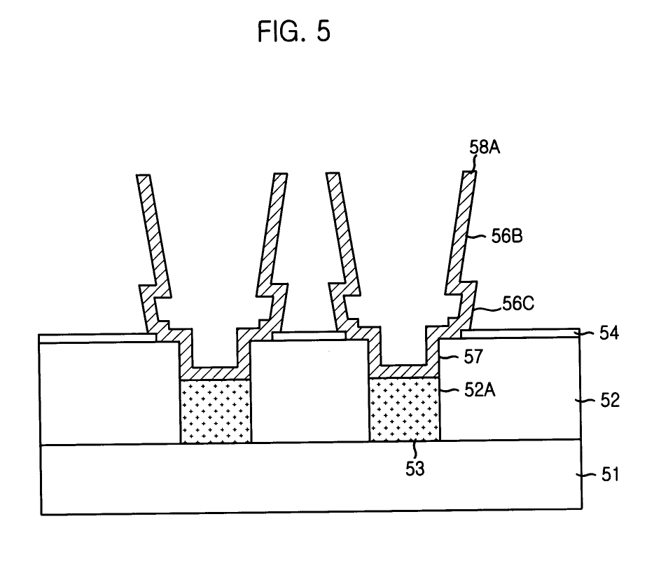

FIG. 5 is a cross-sectional view showing a capacitor structure in accordance with a second preferred embodiment of the present invention.

As shown, the capacitor in accordance with the second preferred embodiment includes: a substrate 51 providing at least a transistor and a bit line; an inter-layer insulating layer 52 formed on the substrate 51; a polysilicon plug 53 forming a partial portion of a contact hole 52A that passes through the inter-layer insulating layer 52 and exposes a partial portion of the substrate 51; a supporting hole 57 filling the rest of the contact hole 52A; and a storage node 58A having a cylinder structure and being connected to the polysilicon plug 33. Particularly, a bottom portion of the storage node 58A is supported by the supporting hole 57. Also, the nitride layer 54 providing a step-like opening also supports the bottom portion of the storage node 58A, which has a step-like shape allowing a partial portion of the bottom portion sits on the nitride layer 54. Meanwhile, the bottom portion of the storage node 58A has a smaller critical dimension than its upper portion.

In such a capacitor illustrated in FIG. 5, it is enhanced with a capability of preventing bridge formation and pulling-out phenomena of the storage node 58A since the bottom portion of the storage node 58A is supported by the step-like shape formed on the nitride layer 54 and the supporting hole 57 provided to the contact hole 32A occupying an upper portion of the polysilicon plug 33.

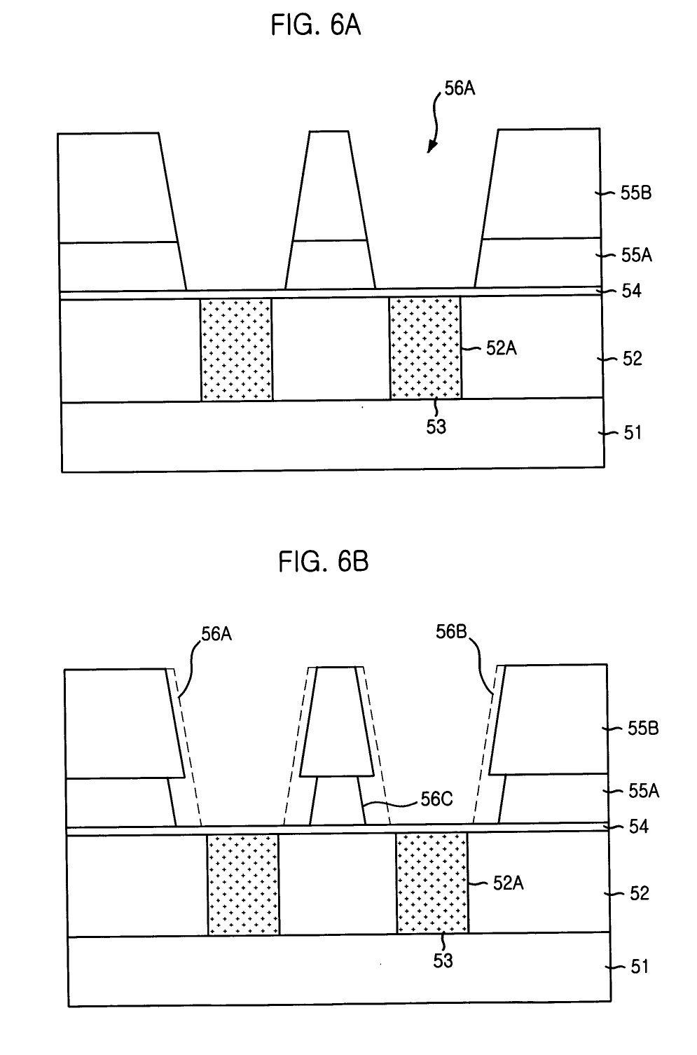

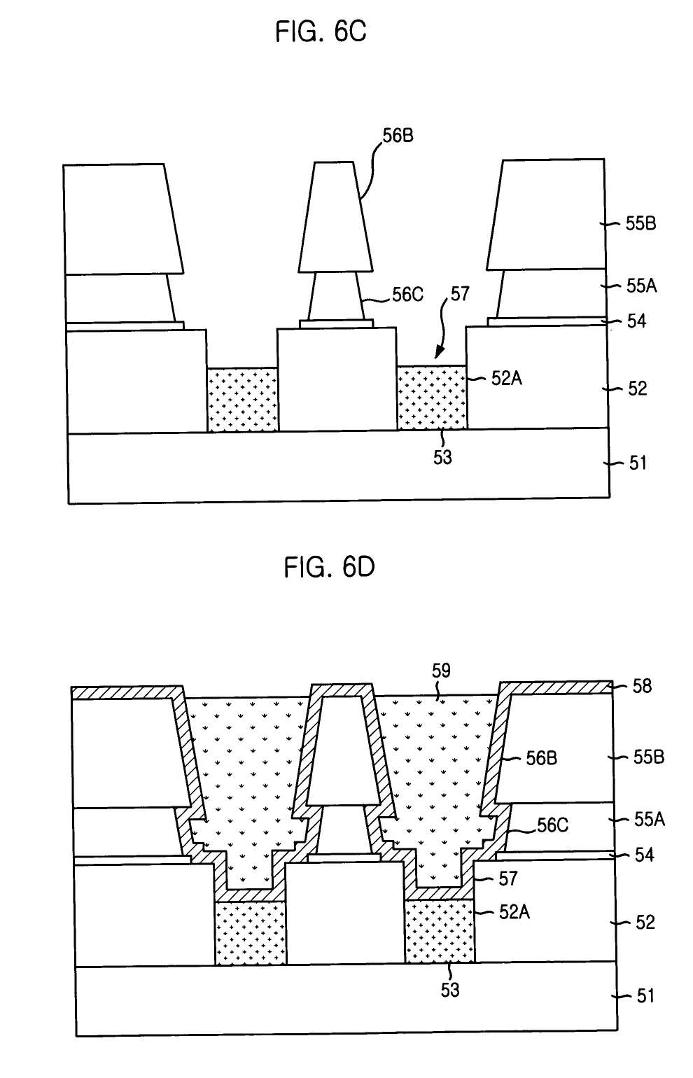

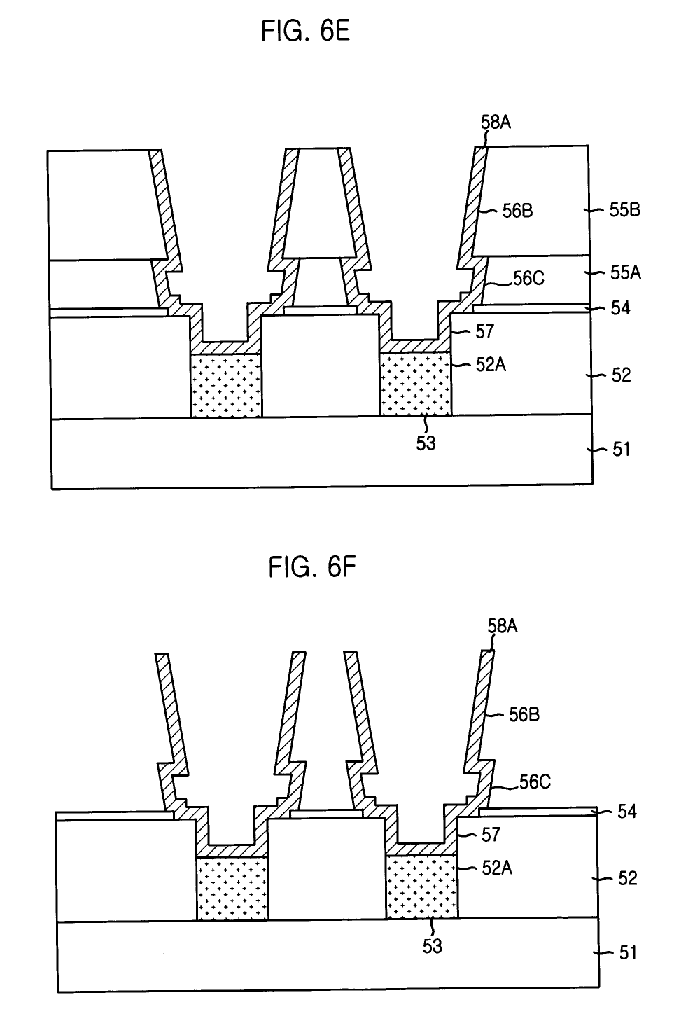

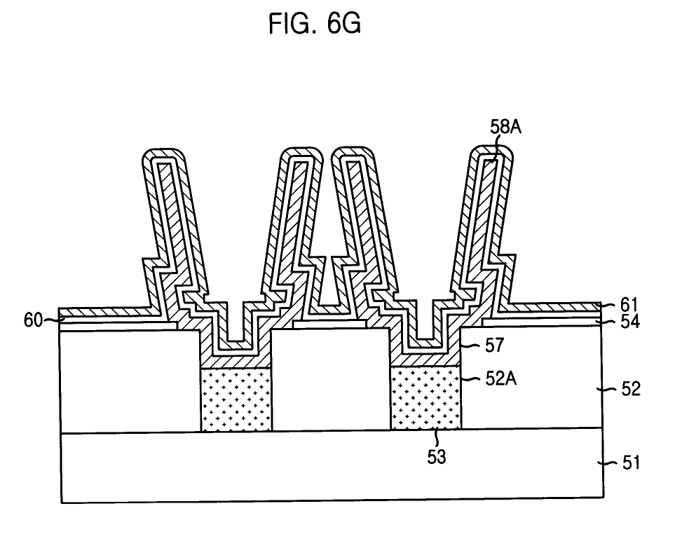

FIGS. 6A to 6F are cross-sectional views demonstrating a method for fabricating the capacitor illustrated in FIG. 5.

Referring to FIG. 6A, the inter-layer insulating layer 52 is formed on the substrate 51 providing a transistor and a bit line. Then, the inter-layer insulating layer 52 is etched to form the contact hole 52A exposing a partial portion of the substrate 51. At this time, the contact hole 52A exposes typically a source/drain region of the transistor, a doped silicon layer, an epitaxially grown silicon layer or the like.

Next, a polysilicon layer is deposited on the inter-layer insulating layer 52 until filling the contact hole 32A, and a recess etch-back process is preformed for planarization and continued until exposing a surface of the inter-layer insulating layer 52. After the planarization of the polysilicon layer, the polysilicon plug 53 is buried into the contact hole 52A. Herein, a surface of the polysilicon plug 53 has the same plane level as that of the inter-layer insulating layer 52.

Subsequently, the nitride layer 54 and a first and a second storage node oxide layers 55A and 55B are sequentially formed on the inter-layer insulating layer 52 including the polysilicon plug 53. At this time, the total thickness of the nitride layer 54 and the first and the second storage node oxide layers 55A and 55B ranges from about 6000 Å to about 20000 Å. In particular, the thickness of the nitride layer 54 ranges from about 100 Å to about 2000 Å. The first and the second storage node oxide layers 55A and 55B are double or stacked oxide layers being deposited through a CVD technique and having different wet etching selectivity and determine the height of the storage node. For instance, the first storage node oxide layer 55A has a higher wet etching selectivity value than that of the second storage node oxide layer 55B. Also, the first and the second storage node oxide layer 55A and 55B use any two materials selected from a group consisting of undoped silicate glass (USG), phospho silicate glass (PSG), boro phospho silicate glass (BPSG) and plasma enhanced tetra ethyl ortho silicate (PETEOS). These selected materials should have different wet etching selectivity values.

Then, a storage node mask is formed on the first and the second storage node oxide layers 55A and 55B and used as an etch mask to perform a dry etching process to the first and the second storage node oxide layers 55A and 55B. The dry etching process is stopped at the nitride layer 54 and the storage node hole 56A is formed thereafter. Hereinafter, the storage node hole 56A is called narrow width storage node hole 56A.

With reference to FIG. 6B, the first and the second storage node oxide layers 55A and 55B are etched by employing a wet dip-out process using a chemical such as a diluted HF, a chemical mixed with HF-based family, a chemical mixed with ammonia-based family. The purpose of the wet etching is to form a wide width storage node hole 56B by widening the narrow width storage node hole 56A. At this time, the dip process using the wet chemical is performed at a temperature of about 4° C. to about 180° C. for about 10 to 1800 seconds.

In case that the first and the second storage node oxide layers 55A and 55B having different wet etch selectivity values are undergone through the dip process, the first storage node oxide layer 55A is etched in a higher rate compared to the second storage node oxide layer 55B, causing a bottom width of the wide width storage node hole 56B to be wider than its upper width. That is, an under-cut region 56C is formed beneath the second storage node oxide layer 55B as the first storage node oxide layer 55A is etched in a higher rate.

Additionally, the nitride layer 54, which is an etch barrier layer, is not etched due to its etch selectivity, thereby preventing losses of the polysilicon plug 53 while performing the dip process using the wet chemical.

With reference to FIG. 6C, the nitride layer 54 is etched to expose the polysilicon plug 53, and then, an upper portion of the polysilicon plug 53 exposed beneath a bottom of the wide width storage node hole 56B is recessed to form the supporting hole 57. At this time, the supporting hole 57 is hollowed in with a predetermined distance from the bottom of the wide width storage node hole 56B. Meanwhile, a dry or wet etching process is used to recess the polysilicon plug 53.

As for the dry etching process for recessing or removing a portion of the polysilicon plug 53, an etch selectivity ratio of the polysilicon layer with respect to the first and the second storage node oxide layers 55A and 55B is about 40 to 1, and a target thickness ranges from about 500 Å to about 5000 Å.

As for the wet etching process, a chemical solution of NH₄OH and H₂O mixed in a ratio of about 10:1 to about 1:500 or another chemical solution of HF and HNO₃ mixed in a ratio of about 20:1 to about 1:100 is used. Herein, the above ratio is the volume-based one. Also, the above recessing procedure using such mixing chemical solution takes place in a dipping bath whose temperature is maintained in a range from about 4° C. to about 100° C. for about 5 to 3600 seconds. A target etching thickness ranges from about 500 Å to about 5000 Å.

The supporting hole 57 formation can be also applied to a case that the storage node contact is not a polysilicon plug. That is, the support groove 57 can be formed by recessing or removing a portion of the storage node contact through the use of a dry etch selectivity value greater than a specifically set value and a chemical solution.

Referring to FIG. 6D, the doped silicon layer 58 is deposited on an entire surface including the supporting hole 57 by using a CVD technique. At this time, the doped silicon layer 58 is deposited on corners of the under-cut region 56C and the bottom of the supporting hole 57. Also, it is possible to apply a double or stacked layer of a doped silicon layer and an undoped silicon layer in addition to the doped silicon layer 58.

Next, a photosensitive film, which is an etch-back barrier layer 59, is formed on the doped silicon layer 58 until filling the supporting hole 57 and the wide width storage node hole 56B. At this time, an oxide layer can be used as the etch-back barrier layer 59.

Then, a partial exposure and developing process is performed to make the etch-back barrier layer 59 remain only in the wide width storage node hole 56B.

With reference to FIG. 6E, the doped silicon layer 58 except for a portion formed on the wide width storage node hole 56B proceeds with an etch-back process by using the remaining etch-back barrier layer 59 as an etch barrier so as to form the storage node 58A having a cylinder structure. The storage node 58A is also made of the doped polysilicon layer. Subsequent to the storage node 58A formation, the remaining etch-back barrier layer 59 is removed. The above-described process is called storage node isolation process.

The storage node 58A is formed through the above-described series of etch-back processes and has a structure wherein a bottom portion of the storage node 58A is inserted into the under-cut region 56C and the supporting hole 57. Even though the storage node 38A is formed into the wide width storage node hole 56B whose width becomes narrower going downward, the under-cut region 56C and the supporting hole 57 are precedently formed before forming the storage node 58A formed in a manner that its bottom portion is inserted into the under-cut region 56C and the supporting hole 57. Therefore, the under-cut region 56C and the supporting hole 57 play a role to reinforce the structural strength of the storage node 58A.

Meanwhile, the storage node isolation process can be proceeded by alternatively performing a CMP process to the doped silicon layer 58 until exposing a surface of the second storage node oxide layer 55B after making the photosensitive film or the oxide layer remained only within the wide width storage node hole 56B.

Referring to FIG. 6F, the first and the second storage node oxide layers 55A and 55B are removed through a wet type dip-out process using a HF-based chemical solution. At this time, the wet type dip-out process is taken place at a dipping bath whose temperature is maintained in a range between about 4° C. to about 80° C. for about 10 to 3600 seconds. Since the nitride layer 54 acts as an etch barrier of the wet type dip-out process applied to the first and the second storage node oxide layers 55A and 55B, it is possible to prevent losses of the inter-layer insulating layer 52.

It is also possible to prevent the storage node 58A from falling from its position due to the fact that the nitride layer 54 and the supporting hole 57 more firmly support the bottom portion of the storage node 58A having a cylinder structure. Furthermore, the under-cut region 56C further supports the storage node 58A to stably sit on the nitride layer 54.

Additionally, the storage node 58A has a cylinder structure wherein a bottom region has a higher critical dimension compared to an upper region. Especially, the bottom region has a step-like shape due to the supporting hole 57 and the under-cut region 56C, resulting in an increase of surface area compared to the capacitor shown in FIG. 3.

As shown in FIG. 6G, the dielectric layer 60 and the plate node 61 are sequentially formed on the storage node 58A, whereby the MIS capacitor formation is completed. At this time, the dielectric layer 60 deposition employs a metalorganic chemical vapor deposition (MOCVD) technique or an ALD technique. Particularly, the dielectric layer 60 is deposited to a thickness ranging from about 50 Å to about 500 Å by using any one material selected from a group consisting of SiO₂, SiO₂/Si₃N₄, TaON, Ta₂O₅, TiO₂, Ta—Ti—O, Al₂O₃, HfO₂, HfO₂/Al₂O₃, SrTiO₃, (Ba, Sr)TiO₃ and (Pb, Sr)TiO₃. The plate node 61 is deposited by employing a sputtering technique, a CVD technique or an ALD technique and patterned thereafter. Particularly, the deposition thickness of the plate node 61 ranges from about 500 Å to about 3000 Å by using TiN, Ru, Ir or Pt.

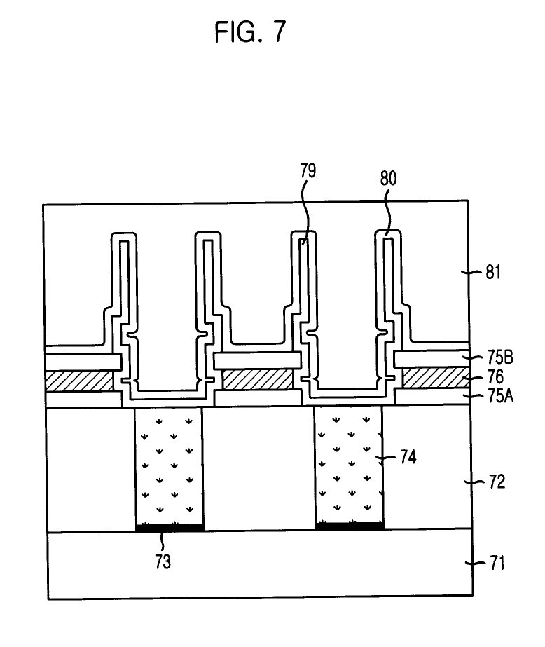

FIG. 7 is a cross-sectional view showing a capacitor structure in accordance with a third preferred embodiment of the present invention.

As shown, the capacitor in accordance with the third preferred embodiment includes: a substrate 71 providing at least a transistor and a bit line; an inter-layer insulating layer 72 formed on the substrate 71; a storage node contact (SNC) including a titanium silicide layer 73 and a storage node contact plug 74 and being connected to the substrate 71 as passing through the inter-layer insulating layer 72; a first and a second nitride layers 75A and 75B being formed on the inter-layer insulating layer 72 and acting as etch barrier layers having an opening exposing a surface of the storage node contact plug 74; a storage node supporting oxide layer 76 exposing the storage node contact plug 74 by having a wider opening that forms an under-cut region between the first and the second nitride layers 75A and 75B; a storage node 79 physically supported by the storage node supporting oxide layer 76 and the second nitride layer 75B and connected to the storage node contact plug 74; a dielectric layer 80 formed on the storage node 79; and a plate node 81 deposited on the dielectric layer 80.

Herein, the storage node 79 has a cylinder structure. Also, a bottom region of the storage node 79 is inserted into the storage node supporting oxide layer 76.

Meanwhile, a partial portion of an upper region of the storage node 79 has the same convexo-concave shape as of the bottom region of the storage node 79. As a result, the surface area of the storage node 79 is increased.

In such a capacitor illustrated in FIG. 7, it is possible to prevent a bridge formation between the storage nodes 79 and a pulling-out of the storage node 79 since the storage node 79 is supported by the first and the second nitride layers 75A and 75B and the storage node supporting oxide layer 76.

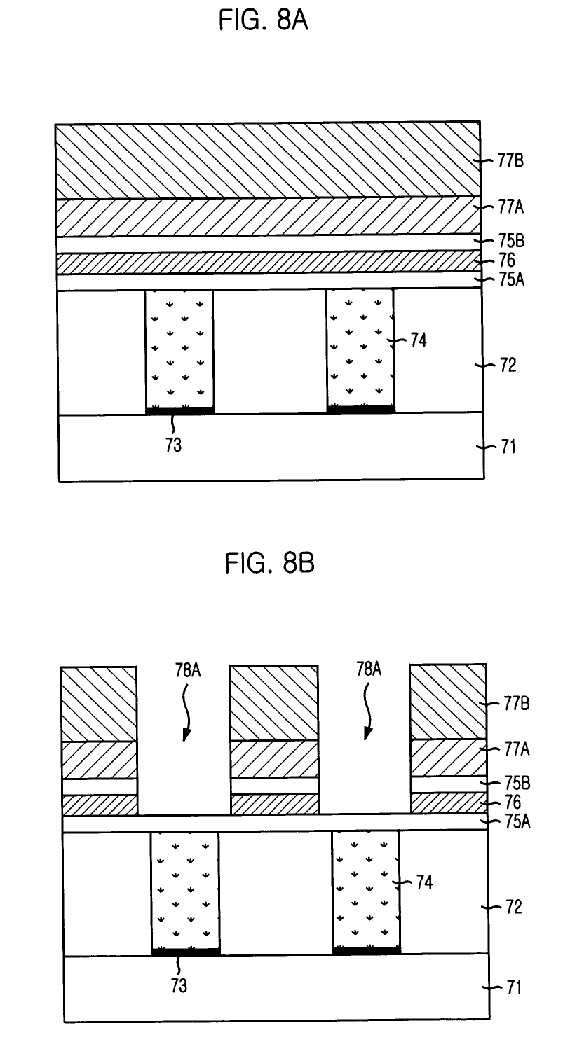

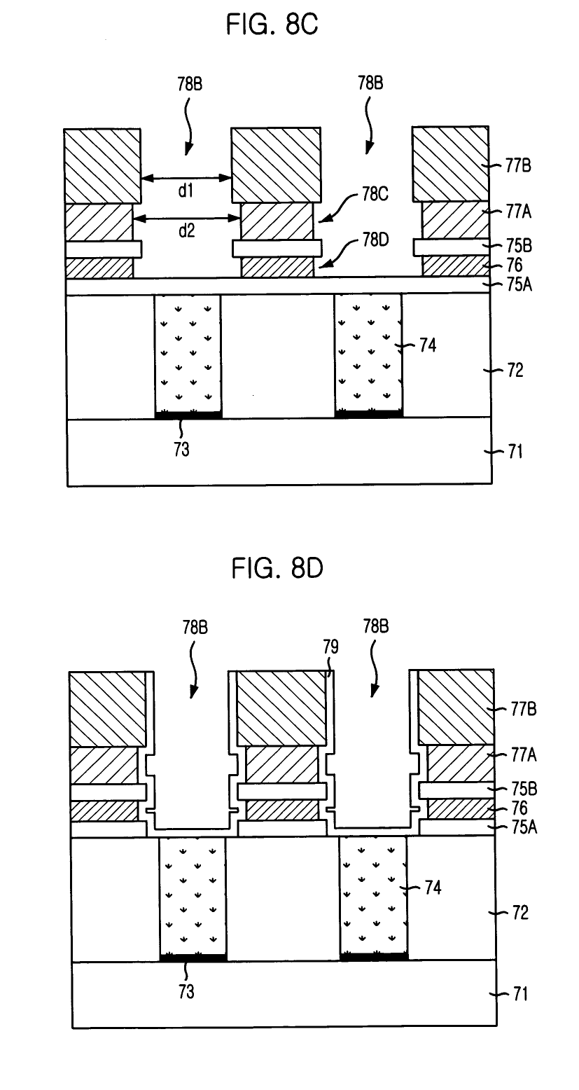

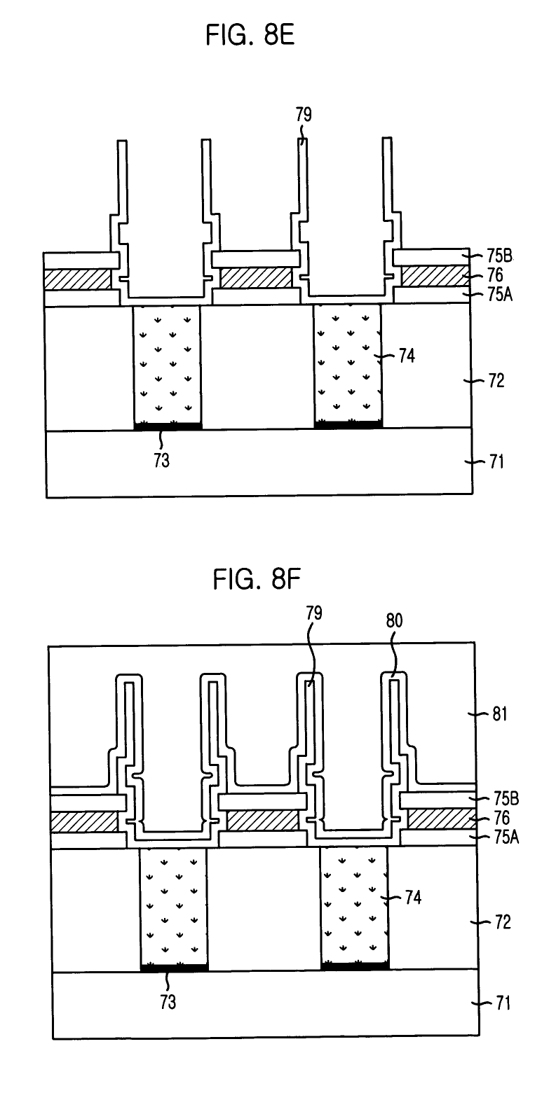

FIGS. 8A to 8F are cross-sectional views showing a method for fabricating the capacitor illustrated in FIG. 7.

Referring to FIG. 8A, the inter-layer insulating layer 72 is formed on the substrate 71 providing a transistor and a bit line. Then, the inter-layer insulating layer 72 is etched to form a storage node contact hole exposing a partial portion of the substrate 71. At this time, the storage node contact hole exposes typically a source/drain region of the transistor, a doped silicon layer, an epitaxially grown silicon layer or the like.

Next, the titanium silicide layer 73 is deposited on the substrate 71 exposed within the storage node contact hole. At this time, the titanium silicide layer 73 is formed by which a titanium layer is deposited and proceeded with a thermal process thereafter. Then, the non-reacted titanium layer is removed through a wet etching process so as to form the titanium silicide layer 73 only within the storage node contact hole. Herein, the titanium silicide layer 73 forms an ohmic contact for reducing contact resistance.

A conductive nitride is deposited on the inter-layer insulating layer 72 until filling the storage node contact hole and planarized through a CMP process until exposing a surface of the inter-layer insulating layer 72 so as to form the storage node contact plug 74 made with the conductive nitride buried into the storage node contact hole.

After forming the storage node contact plug 74, a storage node formation process is subsequently proceeded.

The first nitride layer 75A, the storage node supporting oxide layer 76, the second nitride layer 75B and a first and a second storage node oxide layers 77A and 77B are sequentially formed on the inter-layer insulating layer 72 including the storage node contact plug 74.

Herein, the first and the second nitride layers are etch barrier layers. The storage node supporting oxide layer 76 is used to reinforce the structural strength by supporting a bottom region of the storage node 79. Also, the first and the second storage node oxide layers 77A and 77B are double or stacked layers having different etch selectivity values and determine a height of the storage node 79. For instance, the etch selectivity value of the first storage node oxide layer 77A is higher than that of the second storage node oxide layer 77B.

In addition, the first nitride layer 75A has a thickness of about 100 Å to about 2000 Å, and the second nitride layer 75B has an identical thickness. The storage node supporting oxide layer 76 has a thickness of about 100 Å to about 3000 Å. The total thickness of the first nitride layer 75A, the storage node supporting oxide layer 76, the second nitride layer 75B and the first and the second oxide layers 77A and 77B ranges from about 3000 Å to about 30000 Å. Therefore, the first and the second storage node oxide layer have a thickness of about 7000 Å to about 24000 Å.

In the meantime, the first and the second oxide layers 77A and 77B and the storage node supporting oxide layer 76 are oxide layers deposited through a CVD technique. These oxide layers are also called CVD oxide layer. Hence, the first and the second oxide layers 77A and 77B are multi-layer CVD oxide layers, and use any one material selected from a group consisting of PETEOS, LPTEOS, PSG, BPSG and SOG.

The etch selectivity value of the storage node supporting oxide layer 76 is higher than that of the second storage node oxide layer 77B and approximately the same to the first storage node oxide layer 77A. However, the etch selectivity value of the storage node supporting oxide layer 76 can vary within a range allowing the storage node structure to be maintained. That is, it is the etch selectivity value for preventing an opening of a space between wide width storage node holes neighboring each other during a subsequent wet type dip-out process.

Referring to FIG. 8B, a storage node mask is formed on the first and the second oxide layers 77A and 77B, which are subsequently proceeded with a dry etching with use of the storage node mask as an etch mask. Consecutive to the dry etching, the second nitride layer 75B and the storage node supporting oxide layer 76 are also sequentially proceeded with the dry etching so as to form a region for forming the storage node 79, e.g., a storage node hole 78A which has a concave pattern. Hereinafter, the storage node hole 78A is called narrow width storage node hole 78A. Meanwhile, the fist nitride layer 75A acts as an etch barrier layer for forming the narrow width storage node hole 78A during the dry etching process.

With reference to FIG. 8C, the first and the second storage node oxide layers 77A and 77B are etched through a wet dip-out process using a chemical such as diluted HF, a chemical mixed with HF-based family and a chemical mixed with ammonia-based family so as to widen the narrow width storage node hole 78A. This widened storage node hole 78A is called wide width storage node hole 78B. At this time, the dip process using the wet chemical is performed at a temperature ranging from about 4° C. to about 180° C. for about 10 to 1800 seconds.

When performing the dip process to the first and the second storage node oxide layers 77A and 77B having different etch selectivity values, the first storage node oxide layer 77A is etched in a higher rate compared to the second storage node oxide layer 77B. Hence, a bottom region of the wide width storage node hole 78B has a wider width d₂ than a width d₁ of an upper region of the wide width storage node hole 78B. In other words, a first under-cut region 78C is formed beneath the second storage node oxide layer 77B as the first storage node oxide layer 77A is etched in a higher rate.

Furthermore, the first and the second nitride layers 75A and 75B are not etched due to their etch selectivity. However, the storage node supporting oxide layer 76, which is the same type to the first and the second nitride layers 75A and 75B, is instead etched in wet-type. As a result, a second under-cut region 78D is formed on between the first nitride layer 75A and the second nitride layer 75B.

Eventually, the narrow width storage node hole 78A is widened through a dip process using a wet chemical so as to form the wide width storage node hole 78B. Particularly, the bottom region of the wide width storage node hole 78B becomes wider than its upper region due to the first and the second under-cut regions 78C and 78D.

Meanwhile, since the first nitride layer 75A remains during the above dip process, it is possible to prevent losses of the storage node contact plug 74.

Referring to FIG. 8D, the first nitride layer 75A is removed, and thus, exposing the storage node contact plug 74. Afterwards, a doped silicon layer is deposited on an entire surface including the wide width storage node hole 78B by employing a CVD technique. Then, an oxide layer or a photosensitive film is formed on the doped silicon layer until filling the wide width storage node hole 78B.

Next, the doped silicon layer except for a region providing the wide width storage node hole 78B is removed through an etch-back process or a CMP process so as to form the cylindrical storage node 79 made with the doped silicon layer. The oxide layer or the photosensitive film is removed thereafter.

In the meantime, a conductive layer for the cylindrical storage node 79 can be a double layer deposited with a doped silicon layer and an undoped silicon layer in addition to the single layer of the doped silicon layer. Also, the conductive layer uses Ru, Pt, Ir, W, IrOₓ, RuOₓ, WN, or TiN. The conductive layer is deposited to a thickness of about 100 Å to about 1000 Å by employing a physical vapor deposition (PVD) technique, a CVD technique, an ALD technique or a PEALD technique.

Eventually, the storage node 79 has a cylinder structure wherein a width of the bottom region is wider than that of the upper region. Especially, the surface area of the storage node 79 is increased because the bottom region also has the concavo-convex shape as like the first and the second under-cut regions 78C and 78D.

Referring to FIG. 8E, the first and the second storage node oxide layers 77A and 77B are removed through a wet type dip-out process. At this time, the first and the second nitride layers 75A and 75B remain due to their specific selectivity. These remaining nitride layers 75A and 75B support the bottom region of the storage node 79, thereby preventing the storage node 79 from falling off.

Also, the wet type dip-out process employs a liquid chemical but specifically uses a chemical mixed with HF-based family. The wet type dip-out process is carried out at a temperature ranging from about 4° C. to about 80° C. for about 10 to 3600 seconds.

In comparison with the prior art depicted in FIG. 3, only one nitride layer 25 supports the storage node 28, resulting in problems of falling-off or pulling-out phenomena of the storage node 28 when carrying out the wet type dip-out process to the storage node oxide layer. However, as shown in FIG. 8E, the first and the second nitride layers 75A and 75B support the storage node 79, and the two under-cut regions formed between the first and the second nitride layers 75A and 75B reinforce the structural strength of the storage node 79, thereby further preventing the aforementioned problems.

Referring to FIG. 8F, the dielectric layer 80 and the plate node 81 are sequentially formed on a surface of the storage node 79 exposed after removing the first and the second storage node oxide layers 77A and 77B.

Herein, the dielectric layer 80 deposition employs a MOCVD technique or an ALD technique. Particularly, the dielectric layer 80 is deposited to a thickness ranging from about 50 Å to about 300 Å by using any one material selected from a group consisting of SiO₂, SiO₂/Si₃N₄, TaON, Ta₂O₅, SrTiO₃, (Ba, Sr)TiO₃ and (Pb, Sr)TiO₃.

Also, the plate node 81 is deposited by employing a sputtering technique, a CVD technique or an ALD technique or a PEALD technique. Particularly, the deposition thickness of the plate node 81 ranges from about 500 Å to about 3000 Å by using TiN, Ru, a polysilicon layer, Pt, Ir, W or WN.

As described above, in accordance with the third preferred embodiment, the bottom region of the storage node 79 is firmly supported by the first and the second nitride layers 75A and 75B and the first and the second under-cut regions 78C and 78D formed between the first and the second nitride layer 75A and 75B. This firm support becomes a factor that prevents occurrences of the bridge formation and pulling-out phenomena of the storage node 79 when carrying out the wet type dip-out process using wet chemicals.

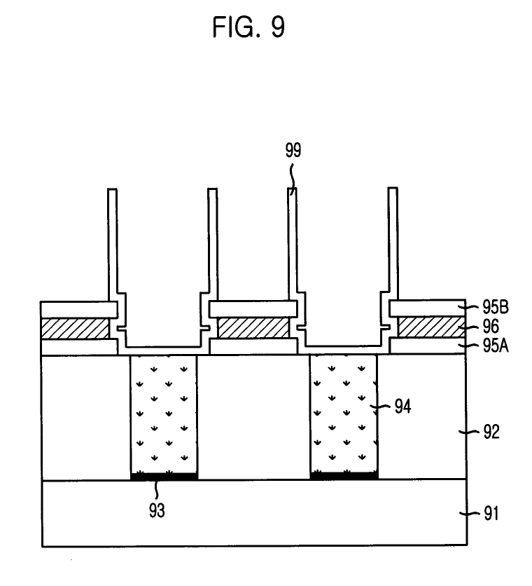

FIG. 9 is a cross-sectional view showing a capacitor in accordance with a fourth preferred embodiment of the present invention.

As shown, the capacitor in accordance with the fourth preferred embodiment includes: a substrate 91 providing at least a transistor and a bit line; an inter-layer insulating layer 92 formed on the substrate 91; a storage node contact (SNC) including a titanium silicide layer 93 and a storage node contact plug 94 and being connected to the substrate 91 as passing through the inter-layer insulating layer 92; a first and a second nitride layers 95A and 95B being formed on the inter-layer insulating layer 92 and acting as etch barrier layers having an opening exposing a surface of the storage node contact plug 94; a storage node supporting oxide layer 96 exposing the storage node contact plug 94 by having a wider opening that forms an under-cut region between the first and the second nitride layers 95A and 95B; a storage node 99 physically supported by the storage node supporting oxide layer 96 and the second nitride layer 95B and connected to the storage node contact plug 94; a dielectric layer 100 formed on the storage node 99; and a plate node 101 deposited on the dielectric layer 100.

Herein, the storage node 99 has a cylinder structure. However, unlike the capacitor illustrated in FIG. 7, an upper region of the storage node 99 has a smooth surface.

In such a capacitor illustrated in FIG. 9, it is possible to prevent bridge formation between the storage nodes 99 and a pulling-out of the storage node 99 since the storage node 99 is supported by the first and the second nitride layers 95A and 95B and the storage node supporting oxide layer 96.

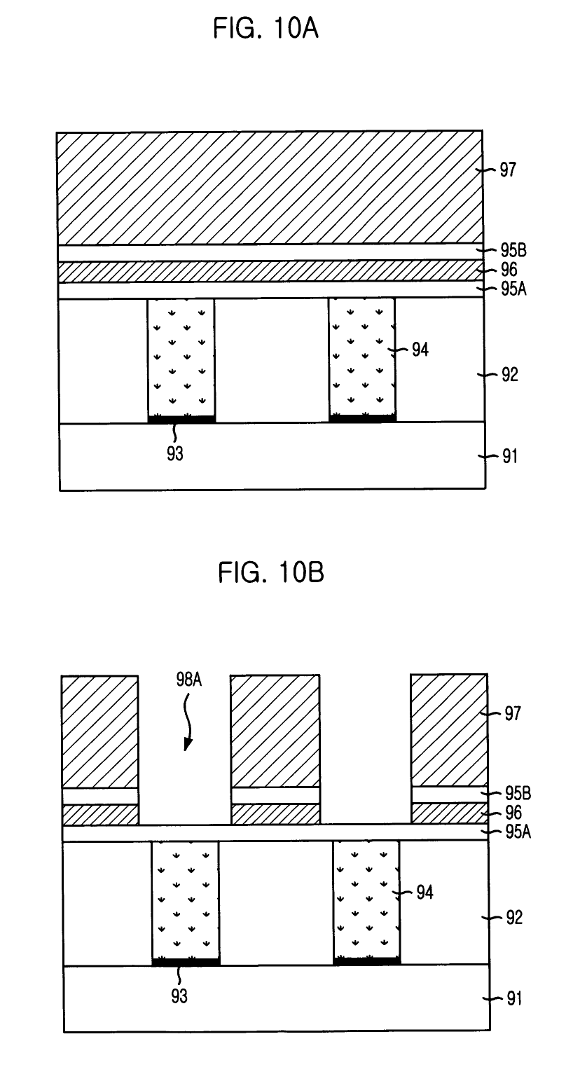

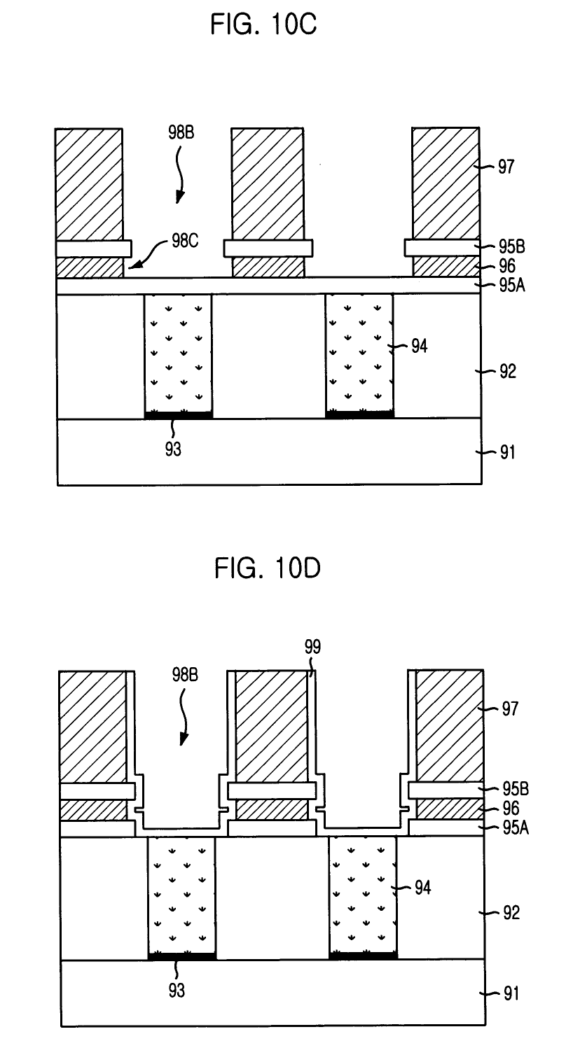

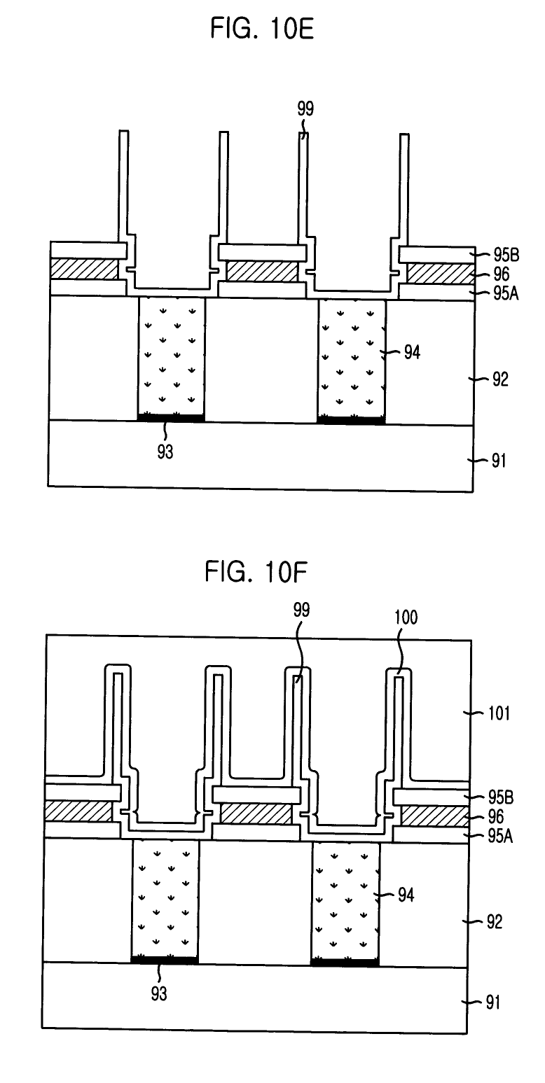

FIGS. 10A to 10F are cross-sectional views showing a method for fabricating the capacitor illustrated in FIG. 9.

Referring to FIG. 10A, the inter-layer insulating layer 92 is formed on the substrate 91 providing a transistor and a bit line. Then, the inter-layer insulating layer 92 is etched to form a storage node contact hole exposing a partial portion of the substrate 91. At this time, the storage node contact hole exposes typically a source/drain region of the transistor, a doped silicon layer, an epitaxially grown silicon layer and so forth.

Next, the titanium silicide layer 93 is deposited on the substrate 91 exposed within the storage node contact hole. At this time, the titanium silicide layer 93 is formed by which a titanium layer is deposited and proceeded with a thermal process thereafter. Then, the non-reacted titanium layer is removed through a wet etching process so as to form the titanium silicide layer 93 only within the storage node contact hole.

A conductive nitride such like TiN is deposited on the inter-layer insulating layer 92 until filling the storage node contact hole and planarized through a CMP process until exposing a surface of the inter-layer insulating layer 92 so as to form the storage node contact plug 94 made with the conductive nitride buried into the storage node contact hole.

After forming the storage node contact plug 94, a storage node formation process is subsequently proceeded.

The first nitride layer 95A, the storage node supporting oxide layer 96, the second nitride layer 95B and a storage node oxide layer 97 are sequentially formed on the inter-layer insulating layer 92 including the storage node contact plug 94.

Herein, the first and the second nitride layers 95A and 95B are etch barrier layers. The storage node supporting oxide layer 96 is used to reinforce the structural strength by supporting a bottom region of the storage node 99. Also, the storage node oxide layer 97 is a single layer deposited through a CVD technique.

In addition, the first nitride layer 95A has a thickness of about 100 Å to about 2000 Å, and the second nitride layer 95B has the identical thickness. The storage node supporting oxide layer 96 has a thickness of about 100 Å to about 3000 Å. The total thickness of the first nitride layer 95A, the storage node supporting oxide layer 96, the second nitride layer 95B and the storage node oxide layer 97 ranges from about 3000 Å to about 30000 Å. Therefore, the storage node oxide layer 97 has a thickness of about 7000 Å to about 24000 Å.

In the meantime, the storage node supporting oxide layer 96 is also an oxide layer deposited through a CVD technique. Also, the wet etch selectivity value of the storage node supporting oxide layer 96 can have approximately the same value of the storage node oxide layer 97. However, the etch selectivity value of the storage node supporting oxide layer 96 can vary within a range allowing the storage node structure to be maintained. That is, it is the etch selectivity value for preventing an opening of a space between wide width storage node holes during a subsequent wet type dip-out process.

Referring to FIG. 10B, a storage node mask is formed on the storage node oxide layers 97, which is subsequently proceeded with a dry etching with use of the storage node mask as an etch mask. After the dry etching, the second nitride layer 95B and the storage node supporting oxide layer 96 are also sequentially proceeded with the dry etching so as to form a region for forming the storage node 99, e.g., a storage node hole 98A which has a concave pattern. Hereinafter, the storage node hole 98A is called narrow width storage node hole 98A. Meanwhile, the fist nitride layer 95A acts as an etch barrier layer for forming the narrow width storage node hole 98A during the dry etching process.

With reference to FIG. 10C, the storage node oxide layer 97 is etched through a wet dip-out process using a chemical such as diluted HF, a chemical mixed with HF-based family and a chemical mixed with ammonia-based family so as to widen the narrow width storage node hole 98A. This widened storage node hole 98A is called the wide width storage node hole 98B. At this time, the dip process using the wet chemical is performed at a temperature ranging from about 4° C. to about 180° C. for about 10 to 1800 seconds.

Furthermore, the first and the second nitride layers 95A and 95B are not etched due to their selectivity values. However, the storage node supporting oxide layer 96, which is the same type of the first and the second nitride layers 95A and 95B, is instead etched in wet-type. As a result, an under-cut region 98C is formed on between the first nitride layer 95A and the second nitride layer 95B.

Eventually, the narrow width storage node hole 98A is widened through the dip process using the wet chemical so as to form the wide width storage node hole 98B. Particularly, a bottom region of the wide width storage node hole 98B becomes wider than its upper region due to the under-cut regions 98C.

Meanwhile, since the first nitride layer 95A remains during the above dip process, it is possible to prevent losses of the storage node contact plug 94.

Referring to FIG. 10D, the first nitride layer 95A is removed, and thus, exposing the storage node contact plug 94. Afterwards, a doped silicon layer is deposited on an entire surface including the wide width storage node hole 98B by employing a CVD technique. Then, an oxide layer or a photosensitive film is formed on the doped silicon layer until filling the wide width storage node hole 98B.

Next, the doped silicon layer formed on regions except for a region providing the wide width storage node hole 98B is removed through an etch-back process or a CMP process so as to form the cylindrical storage node 99 made with the doped silicon layer. The oxide layer or the photosensitive film is removed thereafter. In the meantime, a conductive layer for the cylindrical storage node 99 can be a double layer deposited with a doped silicon layer and an undoped silicon layer in addition to the single layer of the doped silicon layer. Also, the conductive layer uses Ru, Pt, Ir, W, IrOₓ, RuOₓ, WN, or TiN. The conductive layer is deposited to a thickness of about 100 Å to about 1000 Å by employing a PVD technique, a CVD technique, an ALD technique or a PEALD technique.

Eventually, the surface area of the storage node 99 is increased because its bottom region also has the concavo-convex shape due to the under-cut region 98C.

Referring to FIG. 10E, the storage node oxide layer 97 is removed through a wet type dip-out process. At this time, the first and the second nitride layers 95A and 95B remain due to their specific selectivity. These remaining nitride layers 95A and 95B support the bottom region of the storage node 99, thereby preventing the storage node 99 from falling off.

Also, the wet type dip-out process employs a liquid chemical but specifically uses a chemical mixed with HF-based family. The wet type dip-out process is carried out at a temperature ranging from about 4° C. to about 80° C. for about 10 to 3600 seconds.

In comparison with the prior art depicted in FIG. 3, only one nitride layer 25 supports the storage node 28, resulting in problems of falling-off and pulling-out phenomena of the storage node 28 when carrying out the wet type dip-out process to the storage node oxide layer 97. However, as shown in FIG. 10E, the first and the second nitride layers 95A and 95B support the storage node 99 and reinforce the structural strength of the storage node 99, thereby further preventing the aforementioned problems.

Referring to FIG. 10F, the dielectric layer 100 and the plate node 101 are sequentially formed on a surface of the storage node 99 exposed after removing the storage node oxide layer 97.

Herein, the dielectric layer 100 deposition employs a MOCVD technique or an ALD technique. Particularly, the dielectric layer 100 is deposited to a thickness ranging from about 50 Å to about 300 Å by using any one selected from a group consisting of SiO₂, SiO₂/Si₃N₄, TaON, Ta₂O₅, SrTiO₃, (Ba, Sr)TiO₃ and (Pb, Sr)TiO₃.

Also, the plate node 101 is deposited by employing a sputtering technique, a CVD technique or an ALD technique or a PEALD technique. Particularly, the deposition thickness of the plate node 101 ranges from about 500 Å to about 3000 Å by using TiN, Ru, a polysilicon layer, Pt, Ir, W or WN.

As described above, in accordance with the fourth preferred embodiment, the bottom region of the storage node 99 is firmly supported by the first and the second nitride layers 95A and 95B and the under-cut regions 98C although the storage node oxide layer 97 is a single oxide layer. The above firm support becomes a factor that prevents occurrences of the bridge formation and pulling-out phenomena of the storage node 99 when carrying out the wet type dip-out process using wet chemicals.

Unlike the third and the fourth preferred embodiments, if the second nitride layer is not used, the storage node supporting oxide layer is limited to the CVD oxide layer sufficiently securing a wet etch selectivity value compared to the storage node oxide layer. Also, use of the CVD oxide layer having an appropriate etch selectivity value makes it possible to realize a cylinder structure wherein the bottom region of the storage node is inserted into the storage node supporting oxide layer, thereby providing a stabilized structure.

However, when using the second nitride layer as in the third and the fourth preferred embodiments, it is possible to achieve mass-production since the CVD oxide layer for the storage node supporting oxide layer can be selected without any difficulties.

Thus, the present invention provides a capacitor capable of preventing bridge formation and pulling-out phenomena of a storage node by reinforcing structural strength of the storage node having a cylinder structure. This effect results from the fact that a bottom region of the storage node is supported by a supporting hole provided by recessing a polysilicon plug or by a supporting oxide layer forming two nitride layers and at least one under-cut region. Because of this effect, it is further possible to increase wafer yields 2 or 3 times more than before.

Also, since the bottom region of the storage node has a concavo-convex shape as the supporting hole, the surface area of the storage node is also increased, thereby further increasing capacitance of the capacitor.

While the present invention has been described with respect to certain preferred embodiments, it will be apparent to those skilled in the art that various changes and modifications may be made without departing from the scope of the invention as defined in the following claims.

What is claimed is:

1. A method for fabricating a capacitor of a semiconductor device, comprising the steps of:
forming an inter-layer insulating layer on a substrate;
forming a contact hole exposing a partial portion of the substrate by etching the inter-layer insulating layer;
forming a storage node contact buried into the contact hole such that the surface of the storage node contact is at the same plane level as the surface of the inter-layer insulating layer;
forming a storage node oxide layer on the inter-layer insulating layer;
forming a storage node hole exposing the storage node contact by etching the storage node oxide layer;
forming a supporting hole having a hollow form in a downward direction by partially removing an upper portion of the storage node contact exposed by the storage node hole; and
forming a storage node having a cylinder structure electrically connected to the storage node contact wherein a bottom portion of the storage node is disposed in the supporting hole supported by the supporting hole and the inter-layer insulation layer.

2. The method as recited in claim 1, wherein the storage node contact is a polysilicon plug and an upper portion of the polysilicon plug is recessed or removed at the step of forming the supporting hole.

3. The method as recited in claim 2, wherein at the step of forming the supporting hole, the upper portion of the polysilicon plug is subjected to one of a dry etching process and a wet etching process.

4. The method as recited in claim 3, wherein the dry etching process is carried out by adopting an etch selectivity having a ratio of the polysilicon layer with respect to the storage node oxide layer of about 40 to 1.

5. The method as recited in claim 3, wherein the wet etching process uses one of a chemical solution mixed with NH₄OH at a mixing ratio which ranges from about 10 to about 1 and H₂O at a mixing ratio which ranges from about 1 to about 500, and a chemical solution mixed with HF at a mixing ratio which ranges from about 20 to about 1 and HNO₃ at a mixing ratio which ranges from about 1 to about 100.

6. The method as recited in claim 5, wherein the chemical solution is put into a dipping bath in which temperature is maintained in a range from about 4° C. to about 100° C. for about 5 seconds to about 3600 seconds.

7. The method as recited in claim 3, wherein, at the step of forming the supporting hole, a target thickness of the polysilicon plug ranges from about 50 Å to about 5000 Å.

8. A method for fabricating a capacitor of a semiconductor device, comprising the steps of:
forming an inter-layer insulating layer on a substrate;
forming a contact hole exposing a partial portion of the substrate by etching the inter-layer insulating layer;
forming a storage node contact buried into the contact hole such that the surface of the storage node contact is at the same plane level as the surface of the inter-layer insulating layer;
forming a storage node oxide layer constructed with a double layer of an upper layer and a lower layer, wherein an etch selectivity ratio of the upper layer formed on the inter-layer insulating layer is higher than that of the lower layer;
forming a storage node hole exposing the storage node contact by etching the storage node oxide layer;
widening a width of the storage node hole and simultaneously forming an under-cut region at the lower layer of the storage node oxide layer;
forming a supporting hole hollowed in a downward direction by removing a partial portion of an upper portion of the storage node contact exposed by the storage node hole whose width is widened; and
forming a storage node having a cylinder structure and being connected electrically to the storage node contact as a bottom region of the storage node within the storage node hole is supported by the supporting hole and the under-cut region.

9. The method as recited in claim 8, wherein the step of widening the storage node hole and simultaneously forming the under-cut region at the lower layer of the storage node oxide layer uses a dip process using a wet chemical.

10. The method as recited in claim 8, wherein the storage node contact is a polysilicon plug, and an upper portion of the polysilicon plug is removed at the step of forming the supporting hole.

11. The method as recited in claim 10, wherein the upper portion of the polysilicon plug is etched using one of a dry type and a wet type process.

12. The method as recited in claim 11, wherein the dry etching has an etch selectivity ratio of the polysilicon layer with respect to the storage node oxide layer of about 40 to about 1.

13. The method as recited in claim 11, wherein the wet etching process uses one of a chemical solution mixed with NH₄OH at a mixing ratio ranges which from about 10 to about 1 and H₂O at a mixing ratio which ranges from about 1 to about 500 and a chemical solution mixed with HF at a mixing ratio which ranges from about 20 to about 1 and HNO₃ having a mixing ratio which ranges from about 1 to about 100.

14. The method as recited in claim 13, wherein the chemical solution is put into a dipping bath at a temperature maintained in a range from about 4° C. to about 100° C. for about 5 seconds to about 3600 seconds.

15. The method as recited in claim 11, wherein at the step of forming the supporting hole, the polysilicon plug has a target thickness ranging from about 50 Å to about 5000 Å.

16. A capacitor for use in a semiconductor device, comprising:
a substrate;
an inter-layer insulating layer having a contact hole exposing a partial portion of the substrate and being formed on the substrate;
a storage node contact providing a supporting hole at an upper region of the contact hole and filling a partial portion of the contact hole; and
a storage node being connected to the storage node contact wherein a bottom portion of the storage node is filled and secured into the supporting hole.

17. The capacitor as recited in claim 16, further comprising a supporting layer formed on the inter-layer insulating layer and providing a step-like opening in addition to the supporting hole.

18. The capacitor as recited in claim 17, wherein the supporting layer is a nitride layer.

19. The capacitor as recited in claim 16, wherein the supporting hole has a depth of about 50 Å to about 5000 Å.

20. The capacitor as recited in claim 16, wherein the storage node contact is a polysilicon plug.

21. A method for fabricating a capacitor of a semiconductor device, comprising the steps of:
forming an inter-layer insulating layer on a substrate;
forming a storage node contact connected to the substrate by passing through the inter-layer insulating layer;
forming a multi-layered insulation supporting element on the inter-layer insulating layer, the multi-layered insulation supporting element exposing the storage node contact and including at least one layer providing an under-cut region; and
forming a cylindrical storage node electrically connected to the storage node contact as a bottom region of the storage node is inserted into the under-cut region of the multi-layered insulation supporting element.

22. The method as recited in claim 21, wherein the step of forming the multi-layered insulation supporting element includes further the steps of:
forming a first etch barrier layer on the inter-layer insulating layer;
forming an insulation layer on the first etch barrier layer;
forming a second etch barrier layer on the insulation layer;
forming an under-cut region in between the first and the second etch barrier layers by selectively removing the insulation layer.

23. The method as recited in claim 22, wherein the step of selectively removing the inter-layer insulating layer employs a wet type dip-out process.

24. The method as recited in claim 22, wherein the insulation layer is an oxide layer formed through a chemical vapor deposition technique, and the first and the second etch barrier layers are nitride layers.

25. A method for fabricating a capacitor of a semiconductor device, comprising the steps of:
forming an inter-layer insulating layer on a substrate;
forming a storage node contact connected to the substrate by passing through the inter-layer insulating layer;
forming a storage node supporting layer on the inter-layer insulating layer such that an insulation layer is inserted into a space between a first etch barrier layer and a second etch barrier layer;
forming a storage node insulating layer on the storage node supporting layer;
forming a storage node hole by etching the storage node insulating layer and the storage node supporting layer to make an etching process stop at the first etch barrier layer;
removing selectively the storage node insulating layer and the storage node supporting layer to widen a width of the storage node hole and simultaneously form an under-cut region in between the second etch barrier layer and the first etch barrier layer;
forming a cylindrical storage node connected to the storage node contact as a bottom region of the storage node formed in the storage node hole is inserted into the under-cut region; and
removing selectively the storage node insulating layer.

26. The method as recited in claim 25, wherein, at the step of widening the width of the storage node hole and forming the under-cut region in between the second etch barrier layer and the first etch barrier layer, the storage node insulating layer and the storage node supporting layer are selectively etched through a dip process using a wet chemical.

27. The method as recited in claim 26, wherein the storage node insulating layer and the storage node supporting layer are oxide layers, and the first and the second etch barrier layers are nitride layers.

28. The method as recited in claim 26, wherein the dip process uses one of diluted HF, a chemical mixed with HF-based family and a chemical mixed with ammonia-based family at a temperature ranging from about 4° C. to about 180° C. for about 10 seconds to about 1800 seconds.

29. The method as recited in claim 25, wherein the step of removing selectively the storage node insulating layer is carried out at a temperature ranging from about 4° C. to about 180° C. for about 10 seconds to about 3600 seconds with use of a HF-based chemical.

30. The method as recited in claim 25, wherein the step of forming the storage node hole is carried out by employing a dry etching process.
